(19) United States
(12) Patent Application Publication
(10) Pub. No.: US 2012/0298183 A1
(43) Pub. Date: Nov. 29, 2012

(54) PHOTOVOLTAIC MODULE HAVING A PHOTOACTIVE LAYER OR SOLAR COLLECTOR HAVING AN SOLAR ABSORBER

(76) Inventors: Isabell Buresch, Illertissen (DE); Oliver Woelflik, Blaubeuren (DE)

(21) Appl. No.: 13/576,281

(22) PCT Filed: Feb. 8, 2011
(86) PCT No.: PCT/EP2011/000582

§ 371 Date: Jul. 31, 2012

(30) Foreign Application Priority Data
Feb. 11, 2010 (DE) 10 2010 007 841.7

(51) Int. Cl. H01L 31/052; H01L 31/042; H01L 31/0232

(52) U.S. Cl. 136/246; 136/259; 136/249

(57) ABSTRACT

The invention relates to a photovoltaic module on the basis of a metal strip substrate, which allows a monolithic interconnection via the layer structure, wherein the substrate surface is structured in such a manner that an increase in efficiency of up to 20 percent is achieved by increasing the surface and reducing the reflection or a targeted reflection. The invention further relates to a solar absorber module on the basis of a metal strip substrate, where the light-optical effect is utilized in the same manner and the efficiency is increased accordingly.

The invention relates to a photovoltaic module having a photoactive layer according to the precharacterizing clause of claim 1, or to a solar collector having a solar absorber according to the precharacterizing clause of claim 12.

Possibilities of structuring surfaces by rolling are already known from the aluminum and steel industries, aluminum and steel sheets being structured for use as bodywork components so that, during the subsequent stretching, no flow lines are visible on the bodywork surface after painting. Examples of methods for structuring the surfaces of working rolls or the strips directly are laser texturing, grinding or abrasive blasting. So-called EBT methods (electron beam texturing) or EDT methods (electro discharge texturing) are also already-known production methods for textured surfaces. This type of roll structuring, however, leads to very rough surfaces with irregular geometrical shapes, which in many applications do not satisfy the requirements for optical or mechanical properties.

Document EP 1 146 971 B1 discloses a mechanically structured sheet of an aluminum alloy, which is suitable for reflector systems in lighting. For these applications, the sheets need to have appropriate photometric properties. The most important photometric properties include a high overall reflection, by which a maximum fraction of the incident light is reflected from the surface. The preferred properties of the sheet surface furthermore include diffuse or nondirectional light reflection. Such properties are achieved by rolling the sheet material with at least one textured working roll. A nondirectional, diffusely reflecting sheet surface is produced, on the entire surface of which randomly shaped microscopic depressions are formed. The depressions should preferably create an inter-engaging configuration of roof tile-like structures lying close to one another or overlapping.

Further applications are known from document EP 1 368 140 B1. In the method described, a metal sheet or metal strip is fed between rolls which have a textured pattern on the surface, and this pattern is transferred over a plurality of rolling passes onto the sheet or strip. The structures imparted by each rolling pass overlap to form the final textured pattern. Such a structure may also be produced by means of a rolling pass between a multiplicity of successively arranged roll pairs. The texturing of an aluminum strip after a multiplicity of rolling passes comprises a microscopic surface pattern. By a minimal degree of deformation, substantially original and undistorted structures predefined by the rolls are sought. Metal sheets produced in this way are preferably employed as lithographic plates or as automobile reflector sheet.

Further lithographic plates are known from document WO 97/31783 A1. The rolled structure is in this case formed as a uniform and nondirectional microstructure, in which the depressions imparted to the surface overlap one another to a large extent or merge into one another.

It is an object of the invention to refine photovoltaic modules and solar collectors so that the efficiency is raised by increasing the effective surface area and reducing the reflection.

This is intended to be achieved by structuring the surface with particular topographical shapes. Conventional CIS thin-film cells are made on glass or glass-ceramic substrates which are expensive, non-flexible and therefore susceptible to fracture during assembly and transport; furthermore, such substrates can only be structured with difficulty and expensively.

With respect to photovoltaic modules, the invention is reflected by the features of claim 1, and with respect to solar collectors by the features of claim 12. The further dependent claims relate to advantageous refinements and developments of the invention.

The invention relates to a photovoltaic module having a photoactive layer, which is applied onto a rolled metal substrate consisting of a metal strip or a sheet produced therefrom, which consists of a Cu or Cu alloy strip, an Al or Al alloy strip, an Fe or Fe alloy strip, a Ti or Ti alloy strip, an Ni or Ni alloy strip or a stainless steel strip. The metal substrate comprises a surface structure having a roughness in the range of Ra=0.01-5 μm and/or Rz=0.01-20 μm. The surface structure comprises depressions having a minimum lateral extent of 0.3-300 μm. The depressions are arranged in an open structure with a lateral extent extending parallel to the strip surface with a length/width ratio of from 3:1 to 1:3, the length being measured in the rolling direction and the width being measured perpendicularly to the rolling direction. The profile void factor λp lies in the range from 0.25 to 0.85

The invention is based on the idea that the surface of a rolled metal substrate in the form of a metal strip or metal sheet for use in a photovoltaic module or a solar collector is subjected to fine configuration of the surface. These structures, equivalent in effect to a parabolic mirror, are formed through to the photoactive layers of a solar cell and optimize the light yield by reduced scattering and directional reflection, so that reflected sunlight strikes the solar cell surface again.

The fine structure may be introduced into an uncoated strip or sheet surface, or already into a surface covered with at least one layer. The rolls necessary for this in order to produce the fine sheet structures are already known in bodywork construction. They comprise, for example, roll surfaces having an electrolytically generated structure and hard chrome plating.

In the context of the invention, open structures are intended to mean a surface configuration on the substrate material which comprises individual depressions on a surface which still has a smooth appearance. Neighboring depressions may for example also touch or slightly overlap, although they do not merge into one another as structural elements in such a way that the topography of the surface only has the appearance of uniform roughness. It is therefore a fine structure formed from a substrate surface by rolling, comprising a more or less smooth undeformed original background of the initial surface topography. For example, the roll structure marketed under the brand name PRETEX is to be understood here. For such surfaces, it is important that the original background of the surface comprises a large surface percentage bearing area.

The depressions with the indicated minimum lateral extent may have circular shapes. Furthermore, oval shapes may also be envisaged. In the case of an elliptical shape, the minimum lateral extent is two times the minor axis of the ellipse. In the case of circular shapes, the minimum lateral extent corresponds to the circle diameter. The various depressions themselves may either vary in their extent throughout the interval in the range 0.3-300 μm, or fluctuate to a small extent about a particular value. For example, a typical value of the minimum lateral extent is 20 μm which, in approximation to a Gaussian normal distribution, has a fluctuation range with a standard deviation of 5 μm. In order to produce uniform structural sizes, narrower limits may also be established in the interval indicated. A certain, albeit small fluctuation range of the minimum extent, once selected, will always occur in practice.

In principle, depressions are arranged in the open structure with a lateral extent extending parallel to the strip surface with a length/width ratio of from 3:1 to 1:3, the length being measured in the rolling direction and the width being measured perpendicularly to the rolling direction. In general, length/width ratios of 1:1 are sought, which correspond to a circular edge boundary line. Depending on the configuration of the depressions and due to strip tension during the rolling, certain stretching may however occur. Depending on the light incidence, the indicated length/width ratios of the structures may have a high efficiency for the light yield.

The conventional roughness parameters Ra and Rz on their own do not yet satisfactorily define the formation of the surface profile shapes. The description of such profile shapes by means of measurement methods is carried out by means of the profile void factor λp. What is important for the profile shapes is in this case that a shape is selected which primarily acts in the same way as a parabolic mirror, in order to correspondingly reinforce light the light yield. The roughness parameters may also be described by means of the Abott bearing area curve tp and the spatial void factor.

The particular advantage is that the structures according to the invention can substantially contribute to an increase in efficiency in photovoltaic modules, which may be up to 20%. During production and processing of the modules by means of optical joining methods, for example by using laser welding methods, the beam input is also positively influenced by the low reflectivity of the surface. Likewise, the solderability is increased by the improvement of the wetting and dewetting properties.

In a preferred configuration of the invention, a compensation layer adjusting for the thermal expansion and/or a diffusion barrier layer may be applied on the metal substrate. With the so-called cte compensation layers, the different thermal expansion behavior of the materials respectively placed in contact with one another, for example the substrate material, the diffusion barrier layer or the photoactive semiconducting layer, is correspondingly adapted and compensated for. The term cte is derived from the initial letters of the designation “coefficient of thermal expansion” which is conventional in technical fields. In this way, the substrate material is adapted in relation to photoactive layers applied thereon.

Advantageously, the compensation layer or the diffusion barrier layer may be made from TiC, WC, TiN, TiNOx, TiOx, Mo, Cr, Co, NiCo, Ni or Invar and/or combinations thereof. By means of such layer combinations, adaptations of the substrate and insulating layer with respect to thermal expansion and bondability can be carried out. In order to ensure reliable adaptation, the cte compensation or diffusion barrier layer may have a layer thickness of 100 nm to 100 μm.

The construction of conventional CIS or CIGS solar modules based on metal is carried out with interconnection by the so-called shingle technique, which is comparatively elaborate and space-intensive. In order to achieve a direct or monolithic interconnection during the production of the solar modules, in an advantageous embodiment of the invention an electrically insulating coating may be applied on the metal substrate, the cte compensation layer or the diffusion barrier layer. The electrically insulating coating may in this case be at least one ceramic layer consisting of Al203, Zr02, Si02, SiOH, Si3N4, AlN or combinations of these layers. In order to ensure reliable electrical insulation, the layer thickness of the coating may be from 100 nm to 100 μm, preferably from 500 nm to 100 μm. The insulating layer additionally prevents surface diffusion of copper during the production of the CIS/CIGS layer.

In an advantageous configuration of the invention, a molybdenum layer may be applied onto the insulating coating and/or onto the rear side of the strip or sheet not provided with a photoactive layer. This layer is used as a metallic rear side contact for a solar cell photoactive layer arranged on this structure, through which the generated current is passed. The layer thickness of the molybdenum layer, which is applied for example by means of sputtering, may be from 3 μm to 200 μm.

In another advantageous configuration, a CIS or CIGS layer comprising a corresponding front contact layer consisting of ZnO and an intermediate layer of CdS, which are arranged by suitable structuring in the predetermined layer structure to form CIS solar cells monolithically interconnected with one another, may be applied as a photoactive coating on the molybdenum layer. With the help of the molybdenum layer as a metallic rear side contact, individual solar cells in the module can be interconnected with one another. By application of the individual layers and layer systems by means of CVD, PVD or galvanic coating methods, the depressions according to the invention may be formed through to the photoactive layers photoactive layers of a solar cell during the fine configuration of the substrate surface, and thus optimize the light yield by reduced or controlled reflection in conjunction with an increase of the useful surface area. The production of such solar cells from compound semiconductors is already known and may be adapted in accordance with the substrate material, where appropriate on the basis of the knowledge of the person skilled in the art. In this way, a photovoltaic module can be produced on the basis of a metal strip substrate, which allows monolithic interconnection by means of the layer structure, the substrate surface being structured in such a way that a rise in efficiency of up to 20% is achieved by a surface area increase and a reflection reduction or controlled reflection.

Advantageously, tubes or channels consisting of copper or a copper alloy for cooling the cells may be welded, soldered or adhesively bonded on the rear side of the metal substrate. Owing to the cooling effect, the liquid circuit on the rear side of the solar cells ensures a higher current yield. Furthermore, the heated liquid may be used to assist heating. The combined photovoltaic/solar thermal module formed in this way has a substantial rise in efficiency compared with conventional systems.

Another aspect of the invention relates to a solar collector having a solar absorber, consisting of a rolled metal substrate consisting of metal strip or a sheet produced therefrom consisting of Cu or Cu alloy strip, an Al or Al alloy strip, an Fe or Fe alloy strip, a Ti or Ti alloy strip, an Ni or Ni alloy strip or a stainless steel strip. The metal substrate, onto which the absorber layer is applied, comprises a surface structure, which may be isotropic, having a roughness in the range of Ra=0.01-5 μm and/or Rz=0.01-20 μm. The surface structure comprises depressions having a minimum lateral extent of 0.3-300 μm. The depressions are arranged in an open structure with a lateral extent extending parallel to the strip surface with a length/width ratio of from 3:1 to 1:3, the length being measured in the rolling direction and the width being measured perpendicularly to the rolling direction. The profile void factor λp lies in the range from 0.25 to 0.85.

This aspect of the invention is based on the same ideas and advantages as already described above with reference to claim 1. In this way, it is possible to produce a solar absorber module based on a metal strip substrate, in which the photooptical effect is utilized in the same way and the efficiency is thereby increased in the same way.

Common advantageous configurations of photovoltaic modules and solar collectors will be described in more detail below as component aspects of the invention.

Preferably, in the photovoltaic modules and solar collectors, the width to depth ratio of the depressions is at least 1:12. Thus, for small ratios, depressions are also envisaged whose depth significantly exceeds the lateral extent parallel to the substrate surface. For larger ratios, substantially flatter structures are introduced into the substrate surface, which are nevertheless still configured so that there is an efficient light yield. Preferably, width to depth ratios which are favorable in terms of production technology as well as their efficiency may be configured in the range from 1:3 to 3:1.

In order to be able to utilize the parabolic mirror effect, the profile shapes of the surface structure must have particular geometries. Advantageously, in the photovoltaic modules and solar collectors, the depressions may be formed hemispherically, pyramidally or with polygonal faces. Such geometries ensure a particularly efficient light yield and may be produced well by rolling methods.

Preferably, the depressions of the surface structure may be produced by means of rolling with structured working rolls, which have a surface comprising spherical cap-shaped, pyramidal or polygonal elevations. The roll surface forms the negative of the fine structure to be introduced into a strip or sheet surface.

Advantageously, the structure may be formed stochastically or regularly periodically. In the case of regularly periodic structures, flat island-shaped regions which have no overlapping structures, or only slightly overlapping structures, under a solar absorber layer, can utilize sunlight particularly efficiently, while between the periodic structures, for example, there may be smooth zones for electrical conductor tracks or other structuring elements.

In an advantageous configuration of the invention, the strip surface to be structured may be blank. Preferably, galvanic coating, PVD, CVD methods, plasma polymerization or wet chemical coating may be used as coating method after the rolling.

Advantageously, the profile void factor λp may lie in the range from 0.5 to 0.8. Advantageously, the spatial void factor λr may lie in the range from 0.49 to 0.8.

Exemplary embodiments of the invention will be explained in more detail with the help of the schematic drawing and the further figures, in which:

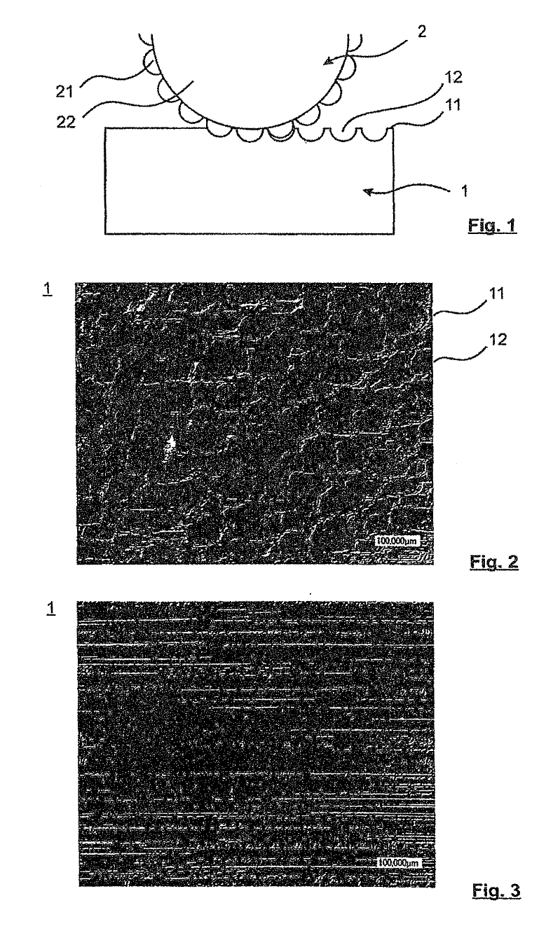

FIG. 1 schematically shows a rolling process on a substrate surface,

FIG. 2 shows a rolled substrate surface comprising an open structure, and

FIG. 3 shows an undeformed substrate surface in the starting state.

Parts which correspond to one another are provided with the same references in all the figures.

FIG. 1 schematically shows a rolling process on the surface of a metal substrate 1. The surface is configured as an open structure. In order to form open structures, individual depressions 12 are rolled in on the metal substrate 1 on an undeformed surface 11 still having a smooth appearance. On the roll body 22 of the roll 2 used, spherical caps 21 are arranged on the surface, which penetrate into the surface of the metal substrate 1. These spherical caps 21 are for example of equal size, so that they generate a uniform negative structure on the substrate surface. As an alternative, however, the structure size of the roll surface may vary somewhat more greatly and also assume other shapes, for example a pyramid shape or cylinder shape. In any event, a fine structure, comprising a more or less smooth undeformed original background of the initial surface, formed by rolling from a substrate surface is involved. Such structures are capable of concentrating the light incident on the surface, in a similar way to a parabolic mirror.

FIG. 2 shows a rolled substrate surface comprising an open structure. In the rolling direction, from left to right in the figure, the depressions 12 are somewhat stretched. This occurs either owing to an increased strip tension during the rolling process or owing to a roll surface comprising structures which are elongated in the rolling direction. In this case, the depressions are formed in an open structure having a lateral extent extending parallel to the strip surface with a length/width ratio of approximately 2:1, the length being measured in the rolling direction, from left to right in FIG. 2, and the width being measured perpendicularly to the rolling direction, from top to bottom in FIG. 2. Remainders of the smooth undeformed surface 11 can still be seen on the surface of the metal substrate 1 between the depressions 12.

For comparison, FIG. 3 shows an undeformed surface of a metal substrate 1 in the original state before the rolling. No depressions have yet been rolled in on this surface, and only fine grinding grooves extending parallel can be seen.

### LIST OF REFERENCES

1 metal substrate
11 undeformed substrate surface
12 depressions
2 roll
21 spherical caps on roll surface
22 Roll body

1. A photovoltaic module having a photoactive layer, which is applied onto a rolled metal substrate consisting of a metal strip or a sheet produced therefrom, which consists of a Cu or Cu alloy strip, an Al or Al alloy strip, an Fe or Fe alloy strip, a Ti or Ti alloy strip, an Ni or Ni alloy strip or a stainless steel strip,
characterized in that
the metal substrate comprises a surface structure having a roughness in the range of Ra=0.01-5 μm and/or Rz=0.01-20 μm,
in that the surface structure comprises depressions having a minimum lateral extent of 0.3-300 μm, and
in that the depressions are arranged in an open structure with a lateral extent extending parallel to the strip surface with a length/width ratio of from 3:1 to 1:3, the length being measured in the rolling direction and the width being measured perpendicularly to the rolling direction,
in that the profile void factor λp lies in the range from 0.25 to 0.85.

2. The photovoltaic module as claimed in claim 1, characterized in that a compensation layer adjusting for the thermal expansion and/or a diffusion barrier layer is applied on the metal substrate.

3. The photovoltaic module as claimed in claim 2, characterized in that the compensation layer or the diffusion barrier layer is made from TiC, WC, TiN, TiNOx, TiOx, Mo, Cr, Co, NiCo, Ni or Invar and/or combinations thereof.

4. The photovoltaic module as claimed in claim 2, characterized in that the compensation or diffusion barrier layer has a layer thickness of 100 nm to 100 μm.

5. The photovoltaic module as claimed in claim 1, characterized in that an electrically insulating coating is applied on the metal substrate, the compensation layer or the diffusion barrier layer.

6. The photovoltaic module as claimed in claim 5, characterized in that the electrically insulating coating is at least one ceramic layer consisting of Al203, Zr02, Si02, SiOH, Si3N4, AlN or combinations of these layers.

7. The photovoltaic module as claimed in claim 5, characterized in that the layer thickness of the electrically insulating coating is from 100 nm to 100 μm, preferably from 500 nm to 100 μm.

8. The photovoltaic module as claimed in claim 7, characterized in that a molybdenum layer is applied onto the insulating coating and/or onto the rear side of the strip or sheet not provided with a photoactive layer.

9. The photovoltaic module as claimed in claim 8, characterized in that the layer thickness of the molybdenum layer is from 3 μm to 200 μm.

10. The photovoltaic module as claimed in claim 8, characterized in that a CIS or CIGS layer comprising a corresponding front contact layer consisting of ZnO and an intermediate layer of CdS, which are arranged by suitable structuring in the predetermined layer structure to form CIS solar cells monolithically interconnected with one another, is applied as a photoactive coating on the molybdenum layer.

11. The photovoltaic module as claimed in claim 10, characterized in that tubes or channels consisting of copper or a copper alloy for cooling the cells are welded, soldered or adhesively bonded on the rear side of the metal substrate.

12. A solar collector having a solar absorber, consisting of a rolled metal substrate consisting of metal strip or a sheet produced therefrom consisting of Cu or Cu alloy strip, an Al or Al alloy strip, an Fe or Fe alloy strip, a Ti or Ti alloy strip, an Ni or Ni alloy strip or a stainless steel strip,
characterized in that
the metal substrate, onto which the absorber layer is applied, comprises a surface structure having a roughness in the range of Ra=0.01-5 μm and/or Rz=0.01-20 μm,
in that the surface structure comprises depressions having a minimum lateral extent of 0.3-300 μm, and
in that the depressions are arranged in an open structure with a lateral extent extending parallel to the strip surface with a length/width ratio of from 3:1 to 1:3, the length being measured in the rolling direction and the width being measured perpendicularly to the rolling direction,
in that the profile void factor λp lies in the range from 0.25 to 0.85.

13. The product as claimed in claim 1, characterized in that the width to depth ratio of the depressions is at least 1:12.

14. The product as claimed in claim 1, characterized in that the depressions are formed hemispherically, pyramidally or with polygonal faces.

15. The product as claimed in claim 14, characterized in that the depressions of the surface structure are produced by means of rolling with structured working rolls, which have a surface comprising spherical cap-shaped, pyramidal or polygonal elevations.

16. The product as claimed in claim 1, characterized in that the structure is formed stochastically or regularly periodically.

17. The product as claimed in claim 1, characterized in that the strip surface to be structured is blank.

18. The product as claimed in claim 1, characterized in that galvanic coating, PVD, CVD methods, plasma polymerization or a wet chemical coating are used as coating method after the rolling.

19. The product as claimed in claim 1, characterized in that the profile void factor λp lies in the range from 0.5 to 0.8.

20. The product as claimed in claim 1, characterized in that the spatial void factor λr lies in the range from 0.49 to 0.8.
